(19) United States
(12) Patent Application Publication
(10) Pub. No.: US 2016/0146900 A1
(43) Pub. Date: May 26, 2016

(54) BATTERY SENSOR ASSEMBLY FOR VEHICLE

(71) Applicant: HYUNDAI MOBIS Co., Ltd., Seoul (KR)

(72) Inventor: Seok Jong YU, Seoul (KR)

(73) Assignee: HYUNDAI MOBIS CO., LTD., Seoul (KR)

(21) Appl. No.: 14/681,387

(22) Filed: Apr. 8, 2015

(30) Foreign Application Priority Data
Nov. 24, 2014 (KR) 10-2014-0164369

(51) Int. Cl. G01R 31/36

(52) U.S. Cl. CPC G01R 31/3696

(57) ABSTRACT

The present invention relates to a battery sensor assembly for a vehicle, and more particularly, to a battery sensor assembly for a vehicle, in which a clamp terminal, a shunt resistor, an attachment terminal, and a printed circuit board are easily assembled.

### CROSS-REFERENCE TO RELATED APPLICATIONS

This application claims priority under 35 U.S.C. §119 to Korean Patent Application No. 10-2014-0164369, filed on Nov. 24, 2014, in the Korean Intellectual Property Office, the disclosure of which is incorporated herein by reference in its entirety.

### TECHNICAL FIELD

The present invention relates to a battery sensor assembly for a vehicle, and more particularly, to a battery sensor assembly for a vehicle, in which a clamp terminal, a shunt resistor, an attachment terminal, and a printed circuit board are easily coupled.

### BACKGROUND

A vehicle is provided with a battery for supplying power to various electric devices.

Here, the battery is discharged during a power supply process, so that a power generator is provided in the vehicle, so that the battery is charged by driving the power generator.

However, when a battery charging time through the power generator is excessively late or early, there is a problem in that the battery is discharged or over-charged.

For this reason, a battery sensor assembly disclosed in Korean Patent No. 10-1222744 (published on Jan. 15, 2013) is installed between a battery and a power generator.

A battery sensor assembly includes a clamp terminal connected to a negative electrode terminal of a battery, a shunt resistor connected to the clamp terminal, a printed circuit board connected to the shunt resistor, and an attachment terminal connected to the shunt resistor, and measures a charging/discharging current of the battery and controls driving of a power generator according to the measured charging/discharging current, so that the battery is prevented from being discharged or over-charged.

In the meantime, in a battery sensor assembly A′ in the related art, a clamp terminal 10′ and a shunt resistor 20′, and the shunt resistor 20′ and an attachment terminal 40′ are typically coupled through brazing as illustrated in FIG. 11.

However, brazing equipment needs to be provided for the brazing, so that there is a problem in that cost is consumed for preparing the brazing equipment, and welding of a filler metal 90 is needed in the next process, such that there is a problem in that time is considerably consumed during a welding process of the filler metal 90, and a plating layer of the attachment terminal 40′ and the like may be peeled, so that there is a problem in that an aesthetic exterior appearance is degraded.

The shunt resistor 20′ and the printed circuit board in the battery sensor assembly A′ in the related art are coupled in such a manner that fixing pins 32 coupled to the shunt resistor 20′ are typically inserted into the printed circuit board (not illustrated) as illustrated in FIG. 12.

However, the fixing pin 32 is coupled to the shunt resistor 20′ by welding, so that there is a problem in that time is considerably consumed for welding the fixing pin 32, and when the fixing pin 32 is miss positioned, there is a problem in that it is difficult to couple the printed circuit board or there is a defect in a coupling position of the printed circuit board.

For this reason, a method of easily coupling a clamp terminal, a shunt resistor, an attachment terminal, and a printed circuit board during a manufacturing process of a battery sensor assembly has been sought in a corresponding field, but a satisfactory result has not been obtained as of yet.

### RELATED ART LITERATURE

### Patent Document

(Patent Document 1) Korean Patent No. 10-1222744

### SUMMARY

The present invention has been made in an effort to provide a battery sensor assembly for a vehicle, which is capable of solving problems in a battery sensor assembly in the related art in that cost is consumed due to preparing of brazing equipment by coupling a clamp terminal and a shunt resistor, and the shunt resistor and an attachment terminal through brazing, time is considerably consumed due to welding of a filler metal, and an aesthetic exterior appearance is degraded due to peeling of a plating layer and the like.

The present invention has also been made in an effort to provide a battery sensor assembly for a vehicle, which is capable of solving problems in a battery sensor assembly in the related art in that time is considerably consumed for welding a fixing pin and it is difficult to couple a printed circuit board or there is a defect in a coupling position of the printed circuit board due to miss positioning of the fixing pin due to coupling of a shunt resistor and an attachment terminal by inserting the fixing pin, which is coupled to the shunt resistor by welding, into the printed circuit board.

An exemplary embodiment of the present invention provides a battery sensor assembly for a vehicle, including: a clamp terminal connected to a negative electrode terminal of a battery; a shunt resistor connected to the clamp terminal; a printed circuit board connected to the shunt resistor; and an attachment terminal connected to the shunt resistor, in which a body of the shunt resistor is fixed by sequentially passing through the attachment terminal, the printed circuit board, and the clamp terminal from a lower side.

The body of the shunt resistor may be formed in a cylindrical shape having a predetermined diameter.

The shunt resistor may be provided with a head part having a larger diameter than that of the body at an end of a lower side of the body.

A nut, which is in contact with an upper surface of the clamp terminal may be fastened to an end of an upper side of the body of the shunt resistor.

A riveting part, which is in contact with an upper surface of the clamp terminal, may be formed at an end of an upper side of the body of the shunt resistor.

A ring-shaped isolator may be coupled to an outer peripheral surface of the body of the shunt resistor, so that the shunt resistor may not be in contact with the attachment terminal, the printed circuit board, and the clamp terminal.

The outer peripheral surface of the body of the shunt resistor may be in contact with the attachment terminal, the printed circuit board, and the clamp terminal by any one method of soldering, screw engagement, and pressing.

The clamp terminal may include a through hole having a diameter equal to or larger than the diameter of the body of the shunt resistor.

The printed circuit board may include a through hole having a diameter equal to or larger than the diameter of the body of the shunt resistor.

The attachment terminal may include a through hole having a diameter equal to or larger than the diameter of the body of the shunt resistor.

Solder patterns may be provided between the clamp terminal and the printed circuit board, and between the printed circuit board and the attachment terminal.

Conductive plates including elastic pieces may be provided between the clamp terminal and the printed circuit board, and between the printed circuit board and the attachment terminal.

Elastic conductive pads may be provided between the clamp terminal and the printed circuit board, and between the printed circuit board and the attachment terminal.

Portions of the clamp terminal, the printed circuit board, and the attachment terminal, through which the shunt resistor passes, may be surrounded by a housing together with the shunt resistor.

The housing may be insert-molded to the portions of the clamp terminal, the printed circuit board, and the attachment terminal, through which the shunt resistor passes.

The housing may include a connector electrically connected to the printed circuit board.

In the battery sensor assembly for the vehicle according to the present invention, the nut is fastened to or the riveting part is formed at the upper end of the shunt resistor, which sequentially passes through the attachment terminal, the printed circuit board, and the clamp terminal from a lower side, so that it is possible to simply couple the clamp terminal, the shunt resistor, the printed circuit board, and the attachment terminal, thereby improving manufacturing efficiency of a battery sensor assembly for a vehicle.

In the battery sensor assembly for the vehicle according to the present invention, the portions of the clamp terminal, the printed circuit board, and the attachment terminal, through which the shunt resistor passes, are surrounded by the housing together with the shunt resistor by an insert-molding method, so that it is possible to prevent a clearance portion from being generated, thereby improving dustproof and waterproof performance and providing an esthetic exterior appearance.

### BRIEF DESCRIPTION OF THE DRAWINGS

FIG. 1 is an exploded perspective view of a battery sensor assembly for a vehicle according to the present invention.

FIG. 2 is a partially cross-sectional view for describing coupling of a shunt resistor, a clamp terminal, a printed circuit board, and an attachment terminal in the present invention.

FIG. 3 is a diagram of an example of another fixing form of the shunt resistor in the present invention.

FIG. 4 is a diagram of an example for describing a contact of a body of the shunt resistor by soldering in the present invention.

FIG. 5 is a diagram of an example for describing a contact of the body of the shunt resistor by screw engagement in the present invention.

FIG. 6 is a diagram of an example for describing a contact of the body of the shunt resistor by pressing in the present invention.

FIG. 7 is a diagram of an example of application of a solder pattern in the present invention.

FIG. 8 is a diagram of an example of application of a conductive plate including elastic pieces in the present invention.

FIG. 9 is a diagram of an example of application of an elastic conductive pad in the present invention.

FIG. 10 is a diagram of an example of a coupling form of a housing of the present invention.

FIG. 11 is a diagram of an example of a coupling form of a shunt resistor, a clamp terminal, and an attachment terminal in a battery sensor assembly for a vehicle in the related art.

FIG. 12 is a diagram of an example of coupling fixing pins to the shunt resistor in the battery sensor assembly for a vehicle in the related art.

### DETAILED DESCRIPTION OF EMBODIMENTS

Hereinafter, the present invention will be described in detail with reference to the accompanying drawings.

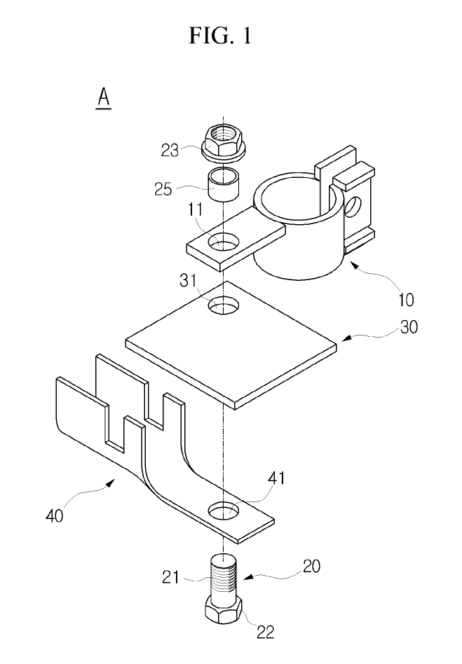

As illustrated in FIG. 1, a battery sensor assembly A for a vehicle according to the present invention includes a clamp terminal 10, a shunt resistor 20, a printed circuit board 30, and an attachment terminal 40.

The clamp terminal 10 is connected to a negative electrode terminal of a battery (not illustrated).

The clamp terminal 10 may include a through hole 11 having a diameter equal to or larger than a diameter of a body 21 of the shunt resistor 20.

The clamp terminal 10 includes the through hole 11 having the diameter equal to or larger than the diameter of the body 21 of the shunt resistor 20, so that the body 21 of the shunt resistor 20 may be inserted through the through hole 11, and thus the shunt resistor 20 may pass through the clamp terminal 10.

The shunt resistor 20 is connected with the clamp terminal 10.

The body 21 of the shunt resistor 20 may be formed in a cylindrical shape having a predetermined diameter.

The body 21 of the shunt resistor 20 is formed in the cylindrical shape having the predetermined diameter, so that the body 21 of the shunt resistor 20 may easily pass through the through hole 11 of the clamp terminal 10, and a through hole 31 of the printed circuit board 30 and a through hole 41 of the attachment terminal 40 which will be described below.

The shunt resistor 20 may be provided with a head part 22 having a larger diameter than that of the body 21 at a lower end of the body 21.

The head part 22 having the larger diameter than that of the body 21 is formed at the lower end of the body 21 of the shunt resistor 20, so that when the shunt resistor 20 sequentially passes through the attachment terminal 40, the printed circuit board 30, and the clamp terminal 10 from a lower side, the head part 22 may be caught by a circumference of the through hole 41 of the attachment terminal 40 to restrict an ascent of the shunt resistor 20, and an electric current may be applied between the shunt resistor 20 and the attachment terminal 40 by a contact between the head part 22 and the attachment terminal 40.

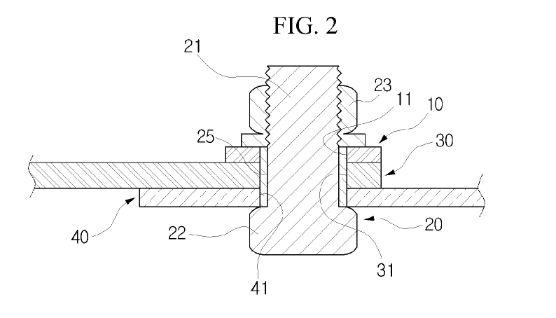

A nut 23, which is in contact with an upper surface of the clamp terminal 10, may be fastened to an end of an upper side of the body 21 of the shunt resistor 20, as illustrated in FIG. 2.

The nut 23, which is in contact with the upper surface of the clamp terminal 10, is fastened to the end of an upper side of the body 21 of the shunt resistor 20, so that a descent of the shunt resistor 20 may be prevented by the nut 23, and the clamp terminal 10, the printed circuit board 30, and the attachment terminal 40, which are stacked under the nut 23, may be firmly in contact with each other by pressure of the nut 23, and an electric current may be applied between the shunt resistor 20 and the clamp terminal 10.

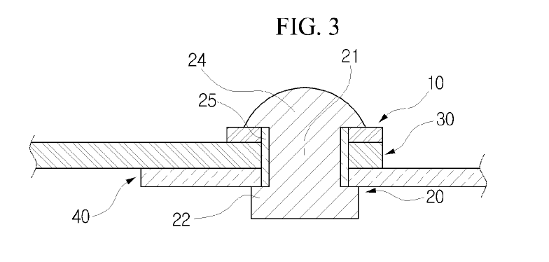

The shunt resistor 20 may be provided with a riveting part 24, which is in contact with the upper surface of the clamp terminal 10, at an end of the upper side of the body 21, as illustrated in FIG. 3.

The riveting part 24, which is in contact with the upper surface of the clamp terminal 10, is formed at the end of the upper side of the body 21 of the shunt resistor 20, so that a descent of the shunt resistor 20 may be prevented by the riveting part 24, and the clamp terminal 10, the printed circuit board 30, and the attachment terminal 40, which are stacked under the riveting part 24, may be firmly in contact with each other by pressure of the riveting part 24, and an electric current may be applied between the shunt resistor 20 and the clamp terminal 10.

An outer peripheral surface of the body 21 of the shunt resistor 20 may be not in contact with the attachment terminal 40, the printed circuit board 30, and the clamp terminal 10.

That is, a ring-shaped isolator 25 is coupled to the outer peripheral surface of the body 21 of the shunt resistor 20, so that the outer peripheral surface of the body 21 of the shunt resistor 20 may not be in contact with the attachment terminal 40, the printed circuit board 30, and the clamp terminal 10.

The outer peripheral surface of the body 21 of the shunt resistor 20 may be in contact with the attachment terminal 40, the printed circuit board 30, and the clamp terminal 10.

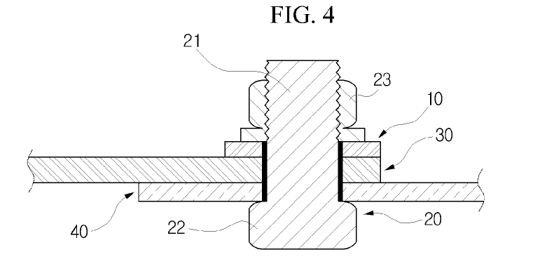

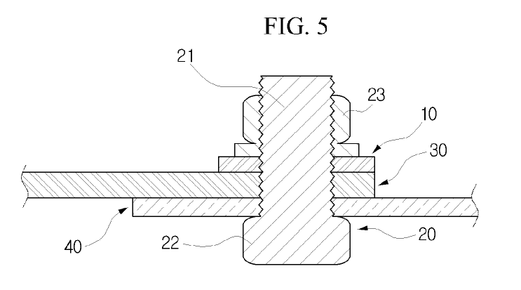

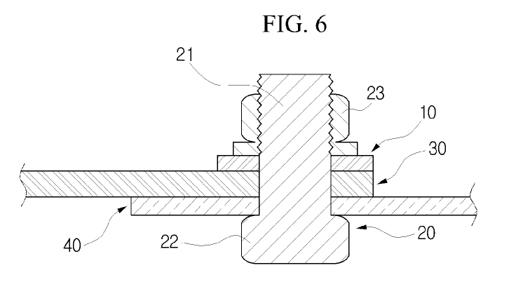

That is, the outer peripheral surface of the body 21 of the shunt resistor 20 is coupled with the attachment terminal 40, the printed circuit board 30, and the clamp terminal 10 by any one method of soldering (a part of which a cross section is expressed dark) as illustrated in FIG. 4, screw engagement as illustrated in FIG. 5, and pressing as illustrated in FIG. 6, so that the outer peripheral surface of the body 21 of the shunt resistor 20 may be in contact with the attachment terminal 40, the printed circuit board 30, and the clamp terminal 10.

The printed circuit board 30 is connected to the shunt resistor 20.

The printed circuit board 30 may include the through hole 31 having a diameter equal to or larger than the diameter of the body 21 of the shunt resistor 20.

The printed circuit board 30 includes the through hole 31 having the diameter equal to or larger than the diameter of the body 21 of the shunt resistor 20, so that the body 21 of the shunt resistor 20 may be inserted through the through hole 31, and thus the shunt resistor 20 may pass through the printed circuit board 30.

The attachment terminal 40 is connected to the shunt resistor 20.

The attachment terminal 40 may include the through hole 41 having a diameter equal to or larger than the diameter of the body 21 of the shunt resistor 20.

The attachment terminal 40 includes the through hole 41 having the diameter equal to or larger than the diameter of a body 21 of the shunt resistor 20, so that the body 21 of the shunt resistor 20 may be inserted through the through hole 41, and thus the shunt resistor 20 may pass through the attachment terminal 40.

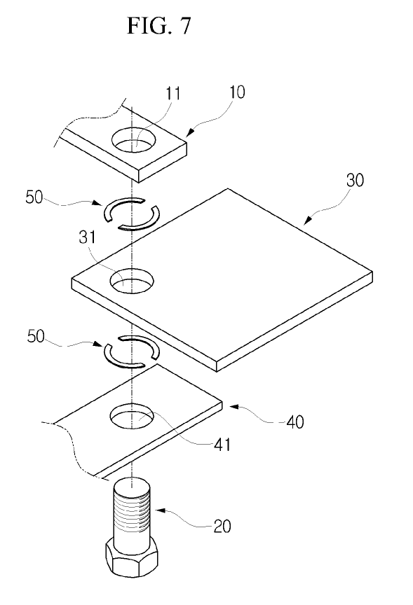

Solder patterns 50 may be provided between the clamp terminal 10 and the printed circuit board 30, and between the printed circuit board 30 and the attachment terminal 40 as illustrated in FIG. 7.

The solder patterns 50 are provided between the clamp terminal 10 and the printed circuit board 30, and between the printed circuit board 30 and the attachment terminal 40, so that an electric current may be applied between the clamp terminal 10 and the printed circuit board 30, and between the printed circuit board 30 and the attachment terminal 40 by the solder patterns 50.

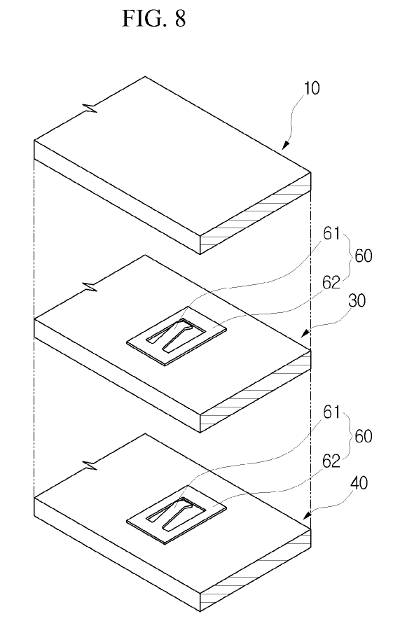

Conductive plates 60 including elastic pieces 61 may be provided between the clamp terminal 10 and the printed circuit board 30, and between the printed circuit board 30 and the attachment terminal 40 as illustrated in FIG. 8.

The conductive plates 60 including the elastic pieces 61 are provided between the clamp terminal 10 and the printed circuit board 30, and between the printed circuit board 30 and the attachment terminal 40, so that an electric current may be applied between the clamp terminal 10 and the printed circuit board 30, and between the printed circuit board 30 and the attachment terminal 40 by the solder patterns 60 by the conductive plates 60 including the elastic pieces 61.

The elastic piece 61 of the conductive plate 60 is a part protruding from a body 62, and is vertically movable between the clamp terminal 10 and the printed circuit board 30, and between the printed circuit board 30 and the attachment terminal 40.

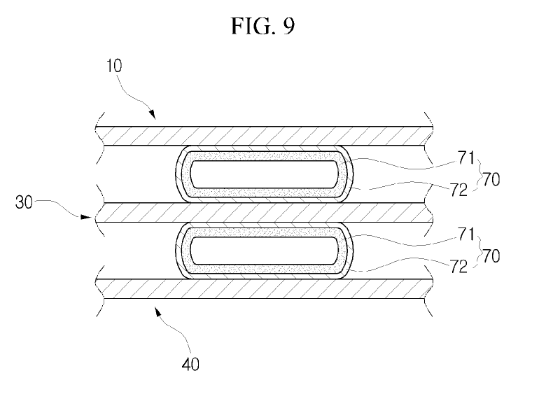

Elastic conductive pads 70 may be provided between the clamp terminal 10 and the printed circuit board 30, and between the printed circuit board 30 and the attachment terminal 40 as illustrated in FIG. 9.

The elastic conductive pads 70 are provided between the clamp terminal 10 and the printed circuit board 30, and between the printed circuit board 30 and the attachment terminal 40, so that an electric current may be applied between the clamp terminal 10 and the printed circuit board 30, and between the printed circuit board 30 and the attachment terminal 40 by the elastic conductive pads 70.

In the elastic conductive pad 70, a conductive layer 72 formed of a metal is provided on an external surface of a cushion layer 71 formed of rubber or silicon, and the cushion layer 71 is vertically elongated or contracted between the clamp terminal 10 and the printed circuit board 30, and between the printed circuit board 30 and the attachment terminal 40.

Portions of the clamp terminal 10, the printed circuit board 30, and the attachment terminal 40, through which the shunt resistor 20 passes, are surrounded by a housing 80 together with the shunt resistor 20.

The portions of the clamp terminal 10, the printed circuit board 30, and the attachment terminal 40, through which the shunt resistor 20 passes, are surrounded by the housing 80 together with the shunt resistor 20, so that the portions of the clamp terminal 10, the printed circuit board 30, and the attachment terminal 40, through which the shunt resistor 20 passes, have aesthetic exterior appearances and waterproof and dustproof performance of the portions of the clamp terminal 10, the printed circuit board 30, and the attachment terminal 40, through which the shunt resistor 20 passes, is improved.

The housing 80 may be insert-molded to the portions of the clamp terminal 10, the printed circuit board 30, and the attachment terminal 40, through which the shunt resistor 20 passes.

The housing 80 is insert-molded to the portions of the clamp terminal 10, the printed circuit board 30, and the attachment terminal 40, through which the shunt resistor 20 passes, so that a clearance portion may be prevented from being generated, thereby preventing degradation in an aesthetic exterior appearance and waterproof and dustproof performance due to generation of the clearance portion.

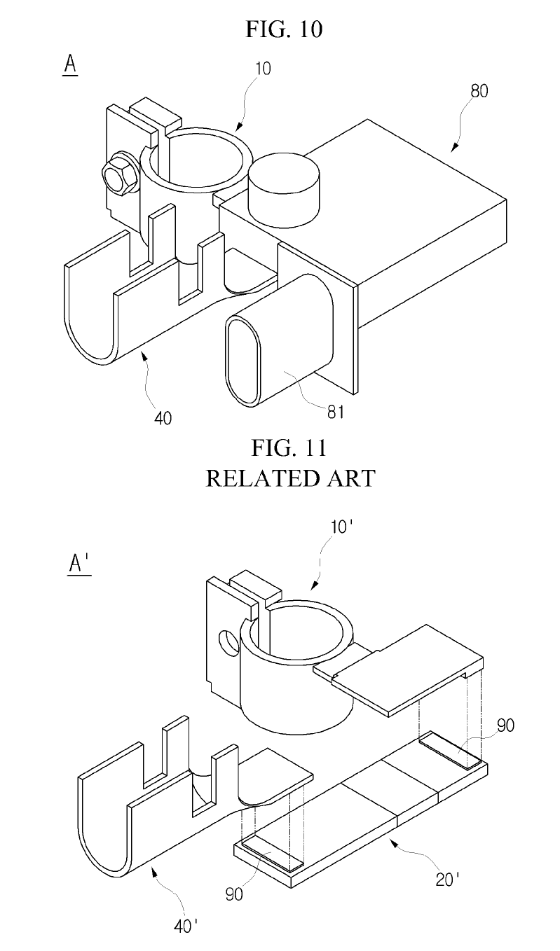

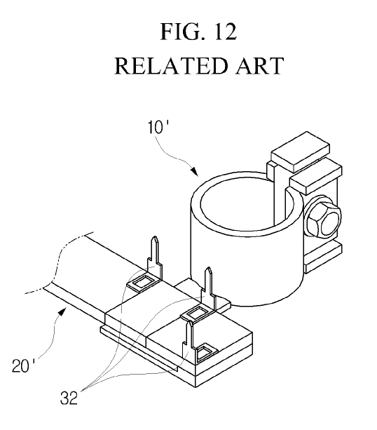

Here, the housing 80 may include a connector 81 which is elastically connected to the printed circuit board 30 as illustrated in FIG. 10.

Since the housing 80 includes the connector 81 which is elastically connected to the printed circuit board 30, another connector provided at an end of a separate cable (not illustrated) is connected to the connector 81, so that it is easy to connect the cable to the housing 80.

The coupling of the clamp terminal 10, the shunt resistor 20, the printed circuit board 30, and the attachment terminal 40 according to the present invention will be described in detail below.

The body 21 of the shunt resistor 20 in the present invention is formed in the cylindrical shape having the predetermined diameter.

The clamp terminal 10, the shunt resistor 20, the printed circuit board 30, and the attachment terminal 40 according to the present invention include the through holes 11, 31, and 41 having the diameters equal to or larger than the diameter of the body 21 of the shunt resistor 20.

Accordingly, the body 21 of the shunt resistor 20 is inserted into the through hole 41 of the attachment terminal 40, the through hole 31 of the printed circuit board 30, and the through hole 11 of the clamp terminal 10 from the lower side, so that the shunt resistor 20 may pass through the attachment terminal 40, the printed circuit board 30, and the clamp terminal 10.

In this case, the shunt resistor 20 is provided with the head part 22 having the diameter larger than the diameter of the body 21 at the lower end of the body 21, so that the lower end of the shunt resistor 20 passing through the attachment terminal 40, the printed circuit board 30, and the clamp terminal 10 is caught by a bottom surface of the attachment terminal 40 by the head part 22 to restrict an ascent of the shunt resistor 20.

In the present invention, the nut 23 may be fastened to or the riveting part 24 is formed at the upper end of the body 21 of the shunt resistor 20, so that the nut 23 is fastened to or the riveting part 24 is formed at the upper end of the shunt resistor 20 in a state where the ascent of the shunt resistor 20 is restricted by the catching of the head part 22, thereby preventing the shunt resistor 20 from descending.

Accordingly, the shunt resistor 20 passing through the attachment terminal 40, the printed circuit board 30, and the clamp terminal 10 may be fixed in the passing state, and a bottom surface of the nut 23 or a lower surface of the riveting part 24 pressurizes the upper surface of the clamp terminal 10, so that the clamp terminal 10, the printed circuit board 30, and the attachment terminal 40, through which the shunt resistor 20 passes, are simply fixed.

In the present invention, the portions of the clamp terminal 10, the printed circuit board 30, and the attachment terminal 40, through which the shunt resistor 20 passes, are surrounded by the housing 80 together with the shunt resistor 20, so that exterior appearances of the portions of the clamp terminal 10, the printed circuit board 30, and the attachment terminal 40, through which the shunt resistor 20 passes, become aesthetic and waterproof and dustproof performance of the portions of the clamp terminal 10, the printed circuit board 30, and the attachment terminal 40, through which the shunt resistor 20 passes, is improved.

Here, a resistance value of the shut resistor 20 coupling the clamp terminal 10, the printed circuit board 30, and the attachment terminal 40 may be varied.

That is, a resistance value of the shunt resistor 20 may be changed by variously changing and selectively applying a length or a cross-sectional area of the shunt resistor 20.

However, when it is difficult to selectively apply the shunt resistor 20, a resistance value of the shunt resistor 20 may be changed by changing a thickness of the clamp terminal 10 or the attachment terminal 40.

In this case, when it is difficult to change the thickness of the clamp terminal 10 or the attachment terminal 40 itself, a resistance value of the shunt resistor 20 may be changed even by coupling a conductive washer (not illustrated) and the like to the clamp terminal 10 or the attachment terminal 40.

A resistance value of the shunt resistor 20 may be varied according to whether the shunt resistor 20 is in contact with the clamp terminal 10, the printed circuit board 30, and the attachment terminal 40.

That is, the ring-shaped isolator 25 is coupled to the outer peripheral surface of the body 21 of the shunt resistor 20, so that the outer peripheral surface of the body 21 of the shunt resistor 20 is not in contact with the clamp terminal 10, the printed circuit board 30, and the attachment terminal 40, and the outer peripheral surface of the body 21 of the shunt resistor 20 is coupled with the attachment terminal 40, the printed circuit board 30, and the clamp terminal 10 by any one method of soldering, screw engagement, and pressing in a state where the ring-shaped isolator 25 is removed between the outer peripheral surface of the body 21 of the shunt resistor 20 and the clamp terminal 10, the printed circuit board 30, and the attachment terminal 40, so that the outer peripheral surface of the body 21 of the shunt resistor 20 is in contact with the clamp terminal 10, the printed circuit board 30, and the attachment terminal 40, and thus a resistance value of the shunt resistor 20 may be changed according to the non-contact.

In this case, a part of the outer peripheral surface of the body 21 of the shunt resistor 20 may be in contact with the clamp terminal 10, the printed circuit board 30, and the attachment terminal 40 according to a length of the ring-shaped isolator 25.

A part of the outer peripheral surface of the body 21 of the shunt resistor 20 may not be in contact with the clamp terminal 10, the printed circuit board 30, and the attachment terminal 40 according to partially performing any one of the soldering, the screw engagement, and the pressing.

In the meantime, the clamp terminal 10 and the printed circuit board 30, and the printed circuit board 30 and the attachment terminal 40 may be electrically in contact with each other.

That is, the solder patterns 50 are provided between the clamp terminal 10 and the printed circuit board 30 and between the printed circuit board 30 and the attachment terminal 40, so that the clamp terminal 10 and the printed circuit board 30, and the printed circuit board 30 and the attachment terminal 40 may be in electrically contact with each other, the conductive plates 60 including the elastic pieces 61 are provided between the clamp terminal 10 and the printed circuit board 30 and between the printed circuit board 30 and the attachment terminal 40, so that the clamp terminal 10 and the printed circuit board 30, and the printed circuit board 30 and the attachment terminal 40 may be in electrically contact with each other, and the elastic conductive pads 70 are provided between the clamp terminal 10 and the printed circuit board 30 and between the printed circuit board 30 and the attachment terminal 40, so that the clamp terminal 10 and the printed circuit board 30, and the printed circuit board 30 and the attachment terminal 40 may be in electrically contact with each other.

As described above, in the battery sensor assembly A for the vehicle according to the present invention, the nut 23 may be fastened to or the riveting part 24 is formed at the upper end of the shunt resistor 20 which sequentially passes through the attachment terminal 40, the printed circuit board 30, and the clamp terminal 10 from the lower side, so that it is possible to simply couple the clamp terminal 10, the shunt resistor 20, the printed circuit board 30, and the attachment terminal 40, thereby improving manufacturing efficiency of the battery sensor assembly for the vehicle, and the portions of the clamp terminal 10, the printed circuit board 30, and the attachment terminal 40, through which the shunt resistor 20 passes, are surrounded by the housing 80 together with the shunt resistor 20 by insert-molding, so that a clearance portion may be prevented from being generated, thereby improving dustproof and waterproof performance and providing an aesthetic exterior appearance.

The present invention described above is not limited to the aforementioned exemplary embodiment, and thus may be changed within a range without departing from the essential point of the present invention claimed in the claims, and the changes belong to the scope of the present invention defined by the description of the claims below.

What is claimed is:

1. A battery sensor assembly for a vehicle, comprising:
a clamp terminal connected to a negative electrode terminal of a battery;
a shunt resistor connected to the clamp terminal;
a printed circuit board connected to the shunt resistor; and
an attachment terminal connected to the shunt resistor,
wherein a body of the shunt resistor is fixed by sequentially passing through the attachment terminal, the printed circuit board, and the clamp terminal from a lower side.

2. The battery sensor assembly of claim 1, wherein the body of the shunt resistor is formed in a cylindrical shape having a predetermined diameter.

3. The battery sensor assembly of claim 1, wherein the shunt resistor is provided with a head part having a larger diameter than that of the body at an end of a lower side of the body.

4. The battery sensor assembly of claim 1, wherein a nut, which is in contact with an upper surface of the clamp terminal, is fastened to an end of an upper side of the body of the shunt resistor.

5. The battery sensor assembly of claim 1, wherein a riveting part, which is in contact with an upper surface of the clamp terminal, is formed at an end of an upper side of the body of the shunt resistor.

6. The battery sensor assembly of claim 1, wherein a ring-shaped isolator is coupled to an outer peripheral surface of the body of the shunt resistor, so that the shunt resistor is not in contact with the attachment terminal, the printed circuit board, and the clamp terminal.

7. The battery sensor assembly of claim 1, wherein an outer peripheral surface of the body of the shunt resistor is in contact with the attachment terminal, the printed circuit board, and the clamp terminal by any one method of soldering, screw engagement, and pressing.

8. The battery sensor assembly of claim 1, wherein the clamp terminal includes a through hole having a diameter equal to or larger than a diameter of the body of the shunt resistor.

9. The battery sensor assembly of claim 1, wherein the printed circuit board includes a through hole having a diameter equal to or larger than a diameter of the body of the shunt resistor.

10. The battery sensor assembly of claim 1, wherein the attachment terminal includes a through hole having a diameter equal to or larger than a diameter of the body of the shunt resistor.

11. The battery sensor assembly of claim 1, wherein solder patterns are provided between the clamp terminal and the printed circuit board, and between the printed circuit board and the attachment terminal.

12. The battery sensor assembly of claim 1, wherein conductive plates including elastic pieces are provided between the clamp terminal and the printed circuit board, and between the printed circuit board and the attachment terminal.

13. The battery sensor assembly of claim 1, wherein elastic conductive pads are provided between the clamp terminal and the printed circuit board, and between the printed circuit board and the attachment terminal.

14. The battery sensor assembly of claim 1, wherein portions of the clamp terminal, the printed circuit board, and the attachment terminal, through which the shunt resistor passes, are surrounded by a housing together with the shunt resistor.

15. The battery sensor assembly of claim 14, wherein the housing is insert-molded to the portions of the clamp terminal 10, the printed circuit board 30, and the attachment terminal 40, through which the shunt resistor 20 passes.

16. The battery sensor assembly of claim 14, wherein the housing includes a connector electrically connected to the printed circuit board.
